(19) United States
(12) Patent Application Publication
(10) Pub. No.: US 2026/0271261 A1
(43) Pub. Date: Sep. 10, 2026

(54) SEMICONDUCTOR STRUCTURE AND MEMORY

(71) Applicant: INSTITUTE OF MICROELECTRONICS OF THE CHINESE ACADEMY OF SCIENCES, Beijing (CN)

(72) Inventors: Di GENG, Beijing (CN); Ling LI, Beijing (CN); Ming LIU, Beijing (CN); Xinlv DUAN, Beijing (CN); Congyan LU, Beijing (CN)

(73) Assignee: INSTITUTE OF MICROELECTRONICS OF THE CHINESE ACADEMY OF SCIENCES, Beijing (CN)

(21) Appl. No.: 18/873,683

(22) PCT Filed: Aug. 24, 2022
(86) PCT No.: PCT/CN2022/114600

§ 371 Date: Dec. 10, 2024

(30) Foreign Application Priority Data
Jun. 10, 2022 (CN) 202210657821.7

(51) Int. Cl. H10B 12/00

(52) U.S. Cl. CPC H10B 12/00

(57) ABSTRACT

Disclosed in the present disclosure are a semiconductor structure and a memory. The semiconductor structure comprises a first transistor. In the first transistor, a first semiconductor channel is arranged around the outer side of a first gate electrode; a first source drain electrode is arranged around a first end of the first gate electrode and is located outside of the first semiconductor channel; and a second source drain electrode is arranged around a second end of the first gate electrode and is located outside of the first semiconductor channel. In a second transistor, a second semiconductor channel is arranged around the outer side of a second gate electrode; a third source drain electrode is arranged around a first end of the second gate electrode and is located outside of the second semiconductor channel; and a fourth source drain electrode is arranged around a second end of the second gate electrode and is located outside of the second semiconductor channel, wherein the second source drain electrode is conductively connected to the second gate electrode. The present disclosure can reduce storage power consumption and increase a read-write bandwidth.

### CROSS-REFERENCE TO RELATED PATENT APPLICATIONS

This application claims a priority from the Chinese Patent Application No. 2022106578217, filed with the Chinese Patent Office on Jun. 10, 2022, entitled “SEMICONDUCTOR STRUCTURE AND MEMORY”, contents of which is incorporated herein by reference in its entirety.

### FIELD OF THE INVENTION

The disclosure relates to the technical field of semiconductor technology, and in particular to a semiconductor structure and a memory.

### BACKGROUND OF THE INVENTION

In current memory with a unit structure of 1T1C (one thin film transistor and one capacitor), when data is read, an amount of charge stored in a capacitor is read. Each time it is read, a portion of the charge in the capacitor will be lost. Therefore, after each read operation, even if the value stored in the unit structure remains unchanged, it is necessary to rewrite the unit structure once more in order to write corresponding value into the capacitor. This device structure both increases power consumption and affects bandwidth for read and write.

### SUMMARY OF THE INVENTION

In view of the above problems, the present disclosure presents a semiconductor structure and a memory capable of reducing storage power consumption and improving bandwidth for read and write.

In a first aspect of the present disclosure, there is provided a semiconductor structure including: a first transistor including a first gate, a first semiconductor channel, a first source drain, and a second source drain, in which the first semiconductor channel is arranged around outside of the first gate, the first source drain is arranged around a first end of the first gate and is located outside the first semiconductor channel, and the second source drain is arranged around a second end of the first gate and is located outside the first semiconductor channel; and a second transistor including a second gate, a second semiconductor channel, a third source drain and a fourth source drain, in which the second semiconductor channel is arranged around outside of the second gate, the third source drain is arranged around a first end of the second gate and is located outside the second semiconductor channel, and the fourth source drain is arranged around a second end of the second gate and is located outside the second semiconductor channel, where the second source drain is connected electrically with the second gate.

In a second aspect of the present disclosure, there is provided a memory including the semiconductor structure described above.

A semiconductor structure and a memory are provided in one or more embodiments of the present disclosure, in which the semiconductor structure is formed by stacking the first transistor and the second transistor such that the second source drain is connected electrically with the second gate. Thereby, the first transistor and the second transistor form a 2T0C structure. The semiconductor structure according to one or more embodiments of the present disclosure will not lose charge in the gate capacitance formed by the gate of the second transistor at the time of data reading. Furthermore, in the working mode of the 2T0C structure formed by the first transistor and the second transistor, it does not need to re-perform a write operation after each read operation, thereby reducing power consumption and improving bandwidth for read and write.

The above description is only an overview of the technical solutions of the present disclosure. In order to be able to more clearly understand the technical means of the present disclosure, which may be implemented in accordance with the contents of the specification, and in order to make the above and other purposes, features, and advantages of the present disclosure more obvious and easy to understand, specific embodiments of the present disclosure are set forth below.

### BRIEF DESCRIPTION OF THE DRAWINGS

In order to more clearly illustrate the technical solutions in the implementation of the present disclosure, the accompanying drawings used in the description of the embodiments will now be briefly described. It will be apparent that the drawings in the following description are some embodiments of the present disclosure and that other drawings can be derived from these drawings without inventive step for a person of ordinary skill in the art.

FIGS. 1, 2, and 3 respectively show schematic diagrams of a semiconductor structure according to one or more embodiments of the present disclosure;

FIG. 4 shows a schematic diagram of a second transistor according to one or more embodiments of the present disclosure;

FIG. 5 shows a schematic diagram of a semiconductor channel according to one or more embodiments of the present disclosure;

FIGS. 6 and 7 show schematic diagrams of electric field distribution at a second end of a gate of a distinct first transistor according to one or more embodiments of the present disclosure, respectively;

FIGS. 8 and 10 show schematic diagrams of a distinct first transistor according to one or more embodiments of the present disclosure, respectively;

FIG. 9 shows a schematic diagram of a gate position of a first transistor according to one or more embodiments of the present disclosure; and FIG. 11 shows a schematic diagram of wiring principle of a memory according to one or more embodiments of the present disclosure.

### DETAILED DESCRIPTION OF THE INVENTION

Embodiments of the present disclosure will be described with reference to the accompanying drawings. It should be understood, however, that these descriptions are merely exemplary and are not intended to limit the scope of the present disclosure. Furthermore, in the following descriptions, descriptions of well-known structures and techniques are omitted to avoid unnecessarily confusing the concepts of the present disclosure.

Various schematic drawings of structures according to embodiments of the present disclosure are shown in the accompanying drawings. These drawings are not to scale, in which certain details have been enlarged and may have been omitted for purposes of clarity. The shapes of the various regions and layers as well as the relative sizes and positional relationships among them shown in the drawings are only exemplary and can be deviated from in practice due to manufacturing tolerances or technical limitations, and the person skilled in the art may additionally design regions/layers with different shapes, sizes, and relative positions according to actual needs.

In the context of the present disclosure, when a layer/element is referred to as being disposed “on” another layer/element, the layer/element can be disposed directly on that another layer/element, or there can be a centered layer/element between them. Alternatively, if a layer/element is disposed “on ”another layer/element in one orientation, the layer/element can be disposed “under” the another layer/element when the orientation is reversed.

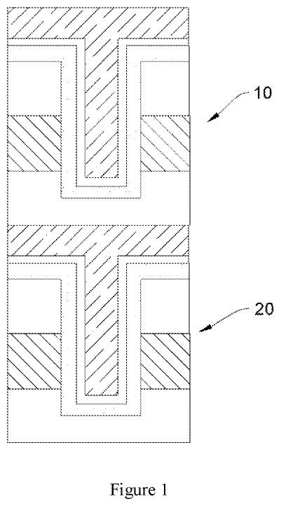

Referring to FIG. 1, in an embodiment of the present disclosure, a semiconductor structure 100 is provided that includes a first transistor 10 and a second transistor 20 that may form a 2T0C memory unit structure in a memory.

The first transistor 10 includes a first gate 11, a first semiconductor channel 13, a first source drain 151, and a second source drain 152. The first semiconductor channel 13 is arranged around outside of the first gate 11. The first source drain 151 is arranged around a first end of the first gate 11 and is located outside the first semiconductor channel 13. The second source drain 152 is arranged around a second end of the first gate 11 and is located outside the first semiconductor channel 13. The second transistor 20 includes a second gate 21, a second semiconductor channel 23, a third source drain 251, and a fourth source drain 252. The second semiconductor channel 23 is arranged around outside of the second gate 21. The third source drain 251 is arranged around a first end of the second gate 21 and is located outside the second semiconductor channel 23. The fourth source drain 252 is arranged around a second end of the second gate 21 and is located outside the second semiconductor channel 23. The second source drain 152 is connected electrically with the second gate 21.

In operation, the first transistor 10 acts as a write transistor and the second transistor 20 acts as a read transistor. When data is read, operating current of the second transistor 20 is read, and the magnitude of the operating current of the second transistor 20 is directly related to the amount of charge stored in the gate capacitor formed by the second gate 21. When data is written, the first transistor 10 discharges the gate of the second transistor 20 through the first semiconductor channel 13 and the second source drain 152, thereby changing an amount of charge stored in the gate capacitor and further controlling operating current of the second transistor 20 to achieve data writing. Therefore, with the semiconductor structure 100 of 2T0C formed by the first transistor 10 and the second transistor 20 according to this embodiment, when data is read, the charge in the gate capacitor formed by the gate of the second transistor 20 will not be lost due to the reading operation. Furthermore, in the working mode of the 2T0C structure formed by the first transistor 10 and the second transistor 20, it does not need to re-perform a write operation after each read operation, thereby reducing power consumption and improving bandwidth for read and write.

Moreover, the first semiconductor channel 13 is arranged around outside of a surface of the first gate 11. The second semiconductor channel 23 is arranged around outside of a surface of the second gate 21. This structure allows a CAA (Channel-All-Around) structure to be formed between the semiconductor channel and the gate. That is, the semiconductor channel surrounds the outside of the gate, which effectively increases the area of the semiconductor channel, boosts the number of carriers in the semiconductor channel, and improves the current conduction efficiency. At the same time, since the semiconductor channel fully surrounds the outside of the gate, the area of the semiconductor channel corresponding to the gate is effectively increased, thereby improving the control ability of the gate on the semiconductor channel. With this design structure, the control area of the gate on the semiconductor channel and the area of the semiconductor channel are increased within a limited volume, thereby achieving relatively small miniaturization.

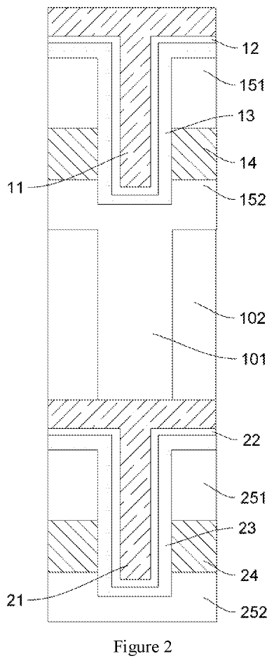

Referring to FIG. 2, the semiconductor structure 100 in the present embodiment may further includes an isolation insulating layer 102 and a connection portion 101. The isolation insulating layer 102 is arranged between the second source drain 152 and the second gate 21 for isolating the second source drain 152 from the second gate 21. The connection portion 101 is arranged in the isolation insulating layer 102, by which the second source drain 152 is connected with the second gate 21. The first transistor 10 is isolated from the second transistor 20 by the isolating insulating layer 102, and the second source drain 152 is connected with the second gate 21 by the connection portion 101, so that parasitic capacitance between the first transistor 10 and the second transistor 20 can be reduced, capacitive coupling effect of the two transistors can be mitigated, and stability of array voltage and data can be improved.

In some embodiments, the isolation insulating layer 102 may be implemented with a material with a relatively low dielectric constant and good insulating properties, such as SiO₂.

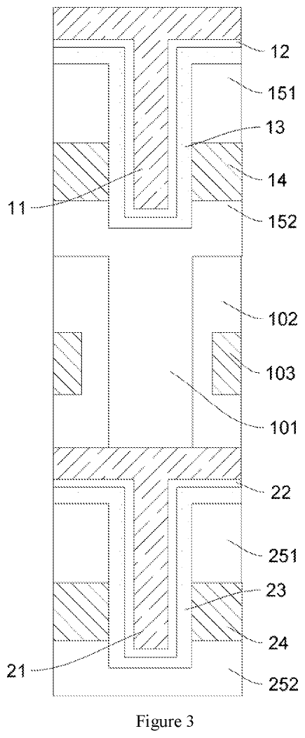

Referring to FIG. 3, in some embodiments, the semiconductor structure 100 further includes a grounding electrode 103. The grounding electrode 103 is arranged around outside of the connection portion 101 with the isolation insulating layer 102 filled between the grounding electrode 103 and the connection portion 101. It is understandable that a storage capacitor can be formed between the grounding electrode 103 and the connection portion 101. Herein, data information is stored in the storage capacitor in addition to being stored in the gate capacitor formed by the second gate 21. That is, the semiconductor structure 100 may form a 2T1C (2 transistors and 1 capacitor) structure after the grounding electrode 103 is added. This implementation method can effectively compensate for the insufficient power when data is stored in 2T0C, and is conducive to achieving a relatively long data retention time.

The first transistor 10 may further include a first gate insulating layer 12. The first gate insulating layer 12 is arranged between the first semiconductor channel 13 and the first gate 11. The second transistor 20 may further include a second gate insulating layer 22. The second gate insulating layer 22 is arranged between the second semiconductor channel 23 and the second gate 21. The gate insulating layers are all used to achieve insulation and isolation between the semiconductor channel and the gate. Both the first gate insulating layer 12 and the second gate insulating layer 22 can be implemented using materials such as HfO, HfAlO, Al₂O₃, etc. Of course, the gate insulating layer can also be formed by combining multiple layers of thin films made of different material, without limitation.

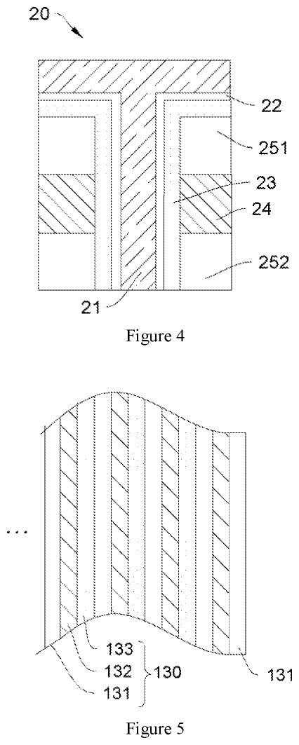

For the second gate insulating layer 22, the second gate 21 can penetrate downward through the second gate insulating layer 22 and the fourth source drain 252, as shown in FIG. 4. The fourth source drain 252 is arranged around a surface of the second semiconductor channel 23 away from the gate and is located at a second end of the second semiconductor channel 23, thereby facilitating wiring. For example, through-silicon via process is adopted for the underpass wiring.

Additionally, if the first end of the second gate 21 is the end close to the first transistor 10, the second gate insulating layer 22 may also completely wrap the second end of the second gate 21, as shown in FIG. 1. At this time, the second semiconductor channel 23 also wraps the second end of the second gate insulating layer 22, that is, the end close to the second end of the second gate 21. The fourth source drain 252 is also arranged around the second end of the second semiconductor channel 23, that is, the end close to the second end of the second gate 21. Such structure enables the second gate 21 to form an electric field at a position of the second semiconductor channel 23 and the fourth source drain 252 away from the first transistor 10, effectively improving the control performance of the second gate 21.

A first transistor 10 may further include a first insulating layer 14. The first insulating layer 14 is arranged around a side of the first gate insulating layer 12 away from the first gate 11 and is located between the first source drain 151 and the second source drain 152. The first insulating layer 14 is used for insulating and isolating the first source drain 151 and the second source drain 152 to avoid a short circuit between them. The second transistor 20 may further include a second insulating layer 24, which is arranged around a side of the second gate insulating layer 22 away from the second gate 21 and is located between the third source drain 251 and the fourth source drain 252. The second insulating layer 24 is used for insulating and isolating the third source drain 251 and the fourth source drain 252 to avoid a short circuit between them.

In some embodiments, the first end of the first gate 11 may penetrate the first source drain 151, i.e., penetrate upwardly, and the first source drain 151 is arranged around a first end of the first semiconductor channel 13. The first end of the first semiconductor channel 13 is the end close to the first end of the first gate 11, which is conducive to wiring, as shown in FIG. 1. The second end of the first semiconductor channel 13 may be completely wrapped by the second source drain 152, and the second end of the first semiconductor channel 13 is the end close to the second end of the first gate 11. Such arrangement is conducive to improving the control ability of the gate. At the same time, the stability of the electrical connection to the connection portion 101 is improved, the conductivity properties are improved, and it can be accomplished in the same deposition process during the manufacturing process.

In some embodiments, the semiconductor structure 100 may further include a substrate. Both the first transistor 10 and the second transistor 20 may be arranged on the same side of the substrate. The lengthwise directions of the first gate 11 and the second gate 21 may be perpendicular to the substrate, or approximately perpendicular to the substrate. This makes the entire transistor device a vertical structure, which is conducive to large-scale stacking with relatively high density. The substrate material may be commonly used substrate material, such as Si, SiO₂, SiC, and the like, or even other flexible substrate materials, without limitation.

The materials of the first gate 11 and the second gate 21 may be ITO, IZO, TiN, etc., which have good conductivity. Additionally, a metal or other highly conductive oxide that facilitates growth by an ALD (Atomic layer deposition) process may also be used.

The materials of the first source drain 151, the second source drain 152, the third source drain 251, and the fourth source drain 252 may be any one or more of TiN, Mo, and W.

Referring to FIG. 5, both the first semiconductor channel 13 and the second semiconductor channel 23 can be implemented with an IGZO material, and the first semiconductor channel 13 and the second semiconductor channel 23 can be implemented with the same or similar structures. The first semiconductor channel 13 and the second semiconductor channel 23 will hereinafter be collectively referred to as a semiconductor channel for ease of expression.

In some embodiments, the semiconductor channel includes a multi-layer thin film structure. The multi-layer thin film structure includes an indium oxide thin film layer 131, a gallium oxide thin film layer 132, and a zinc oxide thin film layer 133. Specifically, the multi-layer thin film structure can be formed by alternately stacking the indium oxide thin film layer 131, the gallium oxide thin film layer 132, and the zinc oxide thin film layer 133. The order for stacking the alternating layers is not limited. The semiconductor channel with a high proportion of indium can achieve a relatively large open state current under the same gate voltage, but threshold voltage of the device is relatively negative, that is, the threshold voltage of the device is less than 0 V and is relatively far away from 0 V. The threshold voltage of the transistor with the semiconductor channel with a low proportion of indium is relatively positive, that is, the threshold voltage of the device is greater than 0 V, or is less than 0 V but is relatively close to 0 V, but open state current of the device will be relatively small. It should be noted that, depending on different requirements for the expected performance of the device, the criteria for judging whether to be positive or negative may vary. For example, −1 V can be used as a reference, values greater than −1 V are considered positive, and values less than −1 V are considered negative. Therefore, in this embodiment, layered structure design allows accurate control of the ratio of each element in indium, gallium, and zinc in manufacturing process, so as to achieve adjustment and balance of turn-off control ability and mobility of the semiconductor channel.

In some embodiments, the multi-layer thin film structure includes a plurality of unit structure layers 130, and the plurality of unit structure layers 130 are stacked sequentially. Each unit structure layer 130 includes an indium oxide thin film layer 131, a gallium oxide thin film layer 132, and a zinc oxide thin film layer 133. With this structure, the indium oxide thin film layer 131, the gallium oxide thin film layer 132 and the zinc oxide thin film layer 133 are stacked cyclically and alternately, thereby effectively improving uniformity of carriers in the semiconductor channel and ensuring a good mobility.

In some embodiments, the thin film layers in the unit structure layer 130 are stacked in sequence from a direction away from the corresponding gate to a direction close to the corresponding gate by the indium oxide thin film layer 131, the gallium oxide thin film layer 132, and the zinc oxide thin film layer 133. It can also be stacked by the zinc oxide thin film layer 133, the indium oxide thin film layer 131 and the gallium oxide thin film layer 132. It can also be stacked by the gallium oxide thin film layer 132, the indium oxide thin film layer 131 and the zinc oxide thin film layer 133, or by the gallium oxide thin film layer 132, the zinc oxide thin film layer 133 and the indium oxide thin film layer 131. Such a stacking structure ensures that the indium oxide thin film layer 131 and the gallium oxide thin film layer 132 are adjacent, thereby effectively suppressing formation of oxygen vacancies and improving controllability of the device.

In some embodiments, the proportion of indium oxide material in the unit structure layer 130 is ⅗ to ¾, and the indium oxide material at this ratio can achieve a relatively large open state current under the same gate voltage condition of the transistor. Further, the proportion of gallium oxide material can be set to be the same as that of zinc oxide material in the unit structure layer 130, so as to ensure that the gate has a good shutdown performance for the semiconductor channel while ensuring that the relatively large open-state current is achieved, thereby achieving a balance between high current and easy shutdown of the semiconductor channel. That is, in some possible implementations, the ratio of InOₓ:GaOₓ:ZnOₓ can be determined in the range from 3:1:1 to 6:1:1, for example, 5:1:1.

In some embodiments, the thickness of each of the indium oxide thin film layer 131, the gallium oxide thin film layer 132, and the zinc oxide thin film layer 133 is less than 1 Å. In this way, even if different layers of compounds are deposited alternately, the final multi-element semiconductor film cannot be seen as a layered structure and can still be equivalently considered as a complete mixture of these elements, thus ensuring other properties of the IGZO material.

The semiconductor channel may further include an outer thin film layer. The outer thin film layer is arranged on a surface of the multi-layer film structure closest to the gate, and the material of the outer thin film layer is indium oxide. That is, an additional layer of indium oxide may be deposited after the last unit structure layer 130 is deposited, thereby obtaining good interface characteristics and improving sub-threshold characteristics and operating current of the device. For example, if the material of the thin film structure of the unit structure layer 130 closest to the gate is ZnOₓ, an additional layer of InOₓ is set on the ZnOₓ to obtain good interface characteristics.

In some embodiments, the thickness of the semiconductor channel is 3 nm to 5 nm, thereby ensuring that the semiconductor channel has a good mobility, and it is conducive to the miniaturization and high-density large-scale array of the entire semiconductor structure 100.

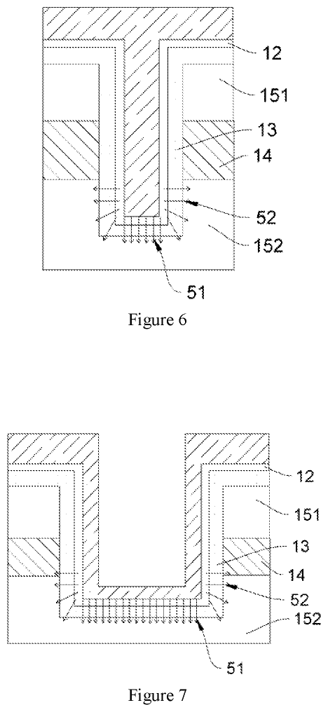

Referring to FIG. 6, in some embodiments, the second source drain 152 is arranged around a second end of the semiconductor channel. That is, the second source drain 152 wraps the gate insulating layer at the second end of the semiconductor channel. The second end of the semiconductor channel and the second end of the gate extend into the second source drain 152. With the gate and the semiconductor channel extending deeply into the second source drain 152, the contact area between the semiconductor channel and the second source drain 152 will be relatively large. Since the gate also extends deeply into the second source drain 152, the second end of the gate can form an electric field (referred to as a first electric field 51 in this embodiment for ease of later expression) in a direction away from the first end of the gate, and can form an electric field (referred to as a second electric field 52 in this embodiment for ease of later expression) in a direction to sides of the semiconductor channel, which are locations where the semiconductor channel is connected with the source drain. Thus, with the structure of the gate and the semiconductor channel extending into the second source drain 152, it can further enhance control ability of the gate on the contact position of the semiconductor channel with the second source drain 152, thereby enhancing performance of the entire device and avoiding generation of leakage current.

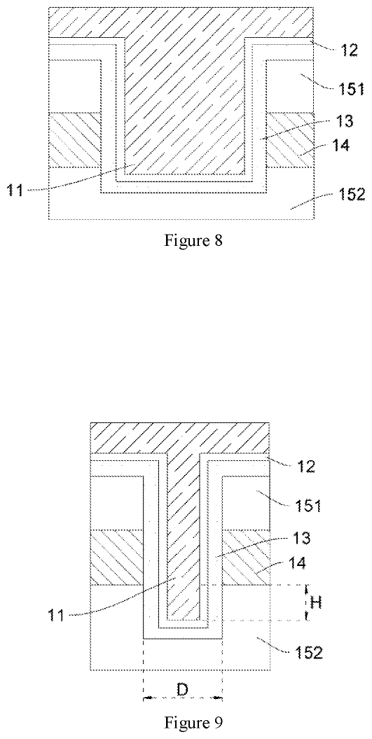

In order to ensure control ability of the second end of the gate on the semiconductor channel, the length of the gate extending into the second source drain 152 can be set to not less than 10 nm, so that there is a sufficient width of the second electric field 52 to ensure a relatively strong control to the semiconductor channel in contact with the second source drain 152. At this time, the diameter of the semiconductor channel extending into the second source drain 152 can be limited to be less than 50 nm to achieve miniaturization of the device. Of course, in other embodiments, the outer diameter of the semiconductor channel can be set relatively large, so that the first electric field 51 generated by the gate can sufficiently cover the second source drain 152, and good gate control may also be achieved, as shown in FIGS. 7 and 8. Moreover, at this time, the control ability of the gate on the second end of the semiconductor channel is mainly determined by the first electric field 51, and thus the length of the gate extending into the second source drain 152 is not limited to less than 10 nm.

However, in some embodiments, if a semiconductor channel with a relatively large outer diameter is used, it may be difficult to reduce the volume of the device. Therefore, in order to ensure that the second end of the gate has a good control performance on the second end of the semiconductor channel, the relationship between the outer diameter of the end of the semiconductor channel extending into the second source drain 152 and the length of the gate extending into the second source drain 152 can be controlled to satisfy the relationship: H≥0.5×(120 nm−D), where H is the length of the gate extending into the second source drain 152, and D is the outer diameter of the end of the semiconductor channel extending into the second source drain 152. At this time, it can be controlled so that D≤100 nm. Thus, a balance between the first electric field 51 and the second electric field 52 is achieved, ensuring the control performance of the gate on the second end of the semiconductor channel, and facilitating further miniaturization and reduction of the device, as shown in FIG. 9. Moreover, when the semiconductor channel extends into the second source drain 152 without penetrating it, both the end surface and the side of the end of the semiconductor channel close to the second source drain 152 are able to form a good contact with the second source drain 152, which effectively reduces the contact resistance. Furthermore, when the diameter of the second end of the semiconductor channel is designed to be larger, the contact area between the semiconductor channel and the second source drain 152 can be further increased to reduce the contact resistance.

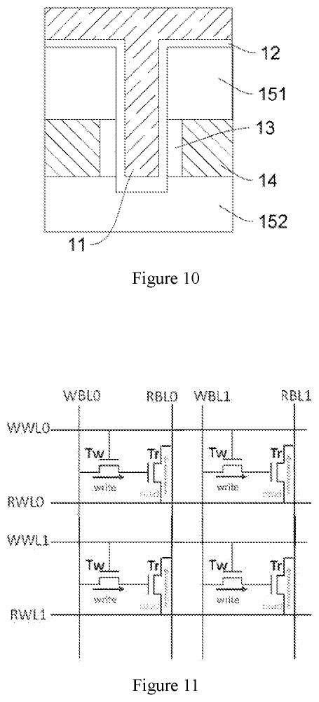

In some embodiments, both the first source drain 151 and the second source drain 152 are arranged around the side of the first gate insulating layer 14 away from the first gate 11. The first source drain 151 is connected with a first end of the first semiconductor channel 13, and the second source drain 152 is connected with a second end of the first semiconductor channel 13. That is, the first source drain 151 and the second source drain 152 are connected at the end of the first semiconductor channel 13, as shown in FIG. 10.

It should be noted that the structural and dimensional relationship between the fourth source drain 252 and the second semiconductor channel 23 can be understood with reference to the structural and dimensional relationship between the second source drain 152 and the first semiconductor channel 13 described above, which will not be repeated in this embodiment.

In summary, according to one or more embodiments of the present disclosure, there is provided a semiconductor structure, in which, by stacking a first transistor 10 and a second transistor 20, a second source drain 152 is connected electrically with a second gate 21, thereby forming a 2T0C structure of the first transistor 10 and the second transistor 20. With this semiconductor structure, when data is read, charge in the gate capacitor formed by the gate of the second transistor 20 will not be lost due to the reading operation. Further, in the working mode of the 2T0C structure formed by the first transistor 10 and the second transistor 20, it does not need to re-perform a write operation after each read operation, thereby reducing storage power consumption and improving bandwidth for read and write.

Based on the same inventive concept, in another embodiment of the present disclosure, there is further provided a memory including the semiconductor structure described in any one of the preceding embodiments. Further, in the memory, the semiconductor structure forms an array as a memory unit array.

Referring to FIGS. 1 and 11, in some embodiments, when wiring is performed in each semiconductor device, a first source drain 151 of a write transistor Tw (first transistor 10) can be connected to a write bit line WBL, and a second source drain 152 can be connected to a second gate 21 of a read transistor Tr (second transistor 20). A first gate 11 of the write transistor Tw can be connected to a write word line WWL. A third source drain 251 of the read transistor Tr can be connected to a read word line RWL, and a fourth source drain 252 of the read transistor Tr may be connected to a read bit line RBL.

It should be noted that the memory provided in this embodiment adopts the semiconductor structure in the above-mentioned embodiment, so the beneficial effects of the memory can be referred to the description in the above-mentioned embodiment, and will not be repeated in this embodiment. In addition, the specific process implementation when the semiconductor structure and each structure in the memory are manufactured can adopt the existing process technology, which is not limited in this embodiment.

In the above description, technical details such as the patterning and etching of each layer have not been described in detail. But those skilled in the art should understand that layers, regions, etc. of the required shape can be formed through various technical means. In addition, in order to form the same structure, those skilled in the art can also design methods that are not exactly the same as the methods described above. In addition, although each embodiment is described separately above, this does not mean that the measures in each embodiment cannot be advantageously combined and used.

Although the preferred embodiments of the present disclosure have been described, once those skilled in the art learn the basic creative concept, other changes and modifications can be made to these embodiments. Therefore, the appended claims are intended to be construed to include the preferred embodiments and all changes and modifications falling within the scope of the present disclosure.

Obviously, those skilled in the art can make various changes and modifications to the present disclosure without departing from the spirit and scope of the present disclosure. In this way, if these modifications and variations of the present disclosure fall within the scope of the claims of the present disclosure and their equivalents, the present disclosure also intends to include these modifications and variations.

1. A semiconductor structure comprising:
a first transistor comprising a first gate, a first semiconductor channel, a first source drain, and a second source drain, wherein the first semiconductor channel is arranged around outside of the first gate, the first source drain is arranged around a first end of the first gate and is located outside the first semiconductor channel, and the second source drain is arranged around a second end of the first gate and is located outside the first semiconductor channel; and
a second transistor comprising a second gate, a second semiconductor channel, a third source drain, and a fourth source drain, wherein the second semiconductor channel is arranged around outside of the second gate, the third source drain is arranged around a first end of the second gate and is located outside the second semiconductor channel, and the fourth source drain is arranged around a second end of the second gate and is located outside the second semiconductor channel, wherein the second source drain is connected electrically with the second gate.

2. The semiconductor structure according to claim 1, further comprising an isolating insulating layer and a connecting portion, wherein the isolating insulating layer is arranged between the second source drain and the second gate, and the connecting portion is arranged in the isolating insulating layer, by which the second source drain is connected with the second gate.

3. The semiconductor structure according to claim 2, further comprising a grounding electrode, wherein the grounding electrode is arranged around outside of the connecting portion with the isolation insulating layer filled between the grounding electrode and the connecting portion.

4. The semiconductor structure according to claim 1, further comprising:
a first gate insulating layer arranged between the first semiconductor channel and the first gate; and
a second gate insulating layer arranged between the second semiconductor channel and the second gate.

5. The semiconductor structure according to claim 1, further comprising:
a first insulating layer arranged around a side of the first gate insulating layer away from the first gate and located between the first source drain and the second source drain; and
a second insulating layer arranged around a side of the second gate insulating layer away from the second gate and located between the third source drain and the fourth source drain.

6. The semiconductor structure according to claim 1, wherein the fourth source drain wraps a second end of the second semiconductor channel, which is the end close to the second end of the second gate.

7. The semiconductor structure according to claim 1, wherein the fourth source drain is arranged around a surface of the second semiconductor channel away from the gate and is located at a second end of the second semiconductor channel, which is the end close to the second end of the second gate.

8. The semiconductor structure according to claim 1, wherein the second source drain wraps a second end of the first semiconductor channel, which is the end close to the second end of the first gate.

9. The semiconductor structure according to claim 1, wherein the materials of each of the first source drain, the second source drain, the third source drain, and the fourth source drain are any one or more of TiN, Mo, and W.

10. A memory comprising the semiconductor structure according to claim 1.
